(19) United States
(12) Patent Application Publication
(10) Pub. No.: US 2025/0239303 A1
(43) Pub. Date: Jul. 24, 2025

(54) 4T TCAM CELL UTILIZING DUAL-GATE TRANSISTORS, 4T TCAM CELL ARRAY, AND METHOD FOR WRITING INFORMATION TO 4T TCAM

(71) Applicant: POSTECH RESEARCH AND BUSINESS DEVELOPMENT FOUNDATION, Pohang-si (KR)

(72) Inventors: Yoonyoung CHUNG, Pohang-si (KR); Taewon SEO, Pohang-si (KR); Seongmin PARK, Pohang-si (KR)

(21) Appl. No.: 19/024,695

(22) Filed: Jan. 16, 2025

(30) Foreign Application Priority Data
Jan. 19, 2024 (KR) 10-2024-0008538
Apr. 19, 2024 (KR) 10-2024-0052665

(51) Int. Cl. G11C 15/04

(52) U.S. Cl. CPC G11C 15/04

(57) ABSTRACT

The present disclosure provides a 4T ternary content addressable memory (TCAM) cell in which one cell is composed of four oxide semiconductor transistors by utilizing oxide semiconductor transistors having a dual-gate structure, a 4T TCAM cell array, and a method for writing information to the 4T TCAM cell. The 4T TCAM cell is connected to one word line, one match line, a bit line, a reverse bit line, a search line, and a reverse search line, and includes: a first write transistor that is a single-gate transistor; a second write transistor that is a single-gate transistor; a first read transistor that is a dual-gate transistor; and a second read transistor that is a dual-gate transistor, wherein the first read transistor, the second read transistor, the first write transistor and the second write transistor are implemented as oxide semiconductors.

### CROSS-REFERENCE TO RELATED APPLICATION

This application claims priorities from and the benefit of Korean Patent Application No. 10-2024-0008538, filed on Jan. 19, 2024, and Korean Patent Application No. 10-2024-0052665, filed on Apr. 19, 2024, and which is hereby incorporated by reference for all purposes as if set forth herein.

### BACKGROUND

### 1. Field

The present disclosure relates to a ternary content addressable memory (TCAM) cell, and more particularly, to a 4T TCAM cell in which one cell is composed of four oxide semiconductor transistors by utilizing oxide semiconductor transistors having a dual-gate structure, a 4T TCAM cell array, and a method for writing information to the 4T TCAM cell.

### 2. Description of Related Art

FIG. 1 illustrates an embodiment of a 2T0C dynamic random access memory (DRAM) cell according to the related art.

Referring to FIG. 1, a 2T0C DRAM cell 100 that includes two transistors and does not use a capacitor C may perform a data writing operation (storage operation) and a data reading operation by combining a write transistor Write TR and a read transistor Read TR with each other.

Data DATA is stored in a gate of the read transistor via the write transistor that is turned on. In this case, when the write transistor is turned off, a charge already stored in the gate of the read transistor will be retained. However, since a small but constant amount of current leaks to the outside through the turned-off write transistor, a data value corresponding to an amount of charge initially stored in the gate of the read transistor may be retained in a corresponding cell only for a predetermined period, and when an amount of charge leaked to the outside increases, the data value will eventually change.

Considering that the data (charge) is stored, a common node between the gate of the read transistor and a drain or a source of the write transistor will be referred to as a storage node (SN) in the following description.

Since a refresh period of the 2T0C DRAM cell is affected by even a small leakage current, a technology that eliminates or minimizes the leakage current has been demanded.

Recently, research into a technology that increases a data retention time to hundreds of seconds by utilizing an oxide semiconductor such as InGaZnO (IGZO) having a very low transistor channel leakage current due to a great band gap of 3 eV or more and low hole mobility to minimize the leakage of a charge through the write transistor has been actively conducted.

FIG. 2 illustrates an oxide semiconductor 2T0C DRAM cell circuit and retention characteristics of an oxide semiconductor 2T0C DRAM cell.

It may be seen that during a retention mode illustrated on the left side of FIG. 2, that is, during a period in which information is stored and then retained in the oxide semiconductor 2T0C DRAM cell, information (charge) stored in a storage node is retained in the oxide semiconductor 2T0C DRAM cell without being substantially leaked through a turned-off read transistor indicated by a dotted line.

Referring to the retention characteristics of the oxide semiconductor 2T0C DRAM cell illustrated on the right side of FIG. 2, it may be seen that a leakage current is relatively lower when using an oxide semiconductor transistor than when using a silicon semiconductor transistor and data is retained for hundreds of seconds or even more than 1,000 seconds.

Recently, research into parallel operations that may quickly process massive amounts of data has been continuously conducted due to the development of artificial intelligence and big data. Accordingly, an interest in content addressable memory (CAM) structures that may perform parallel search and may efficiently perform parallel operations, rather than existing memories such as a static random access memory (SRAM) and a DRAM, has increased. Among them, a ternary content addressable memory (TCAM) that may perform a ternary operation including X (don't care) in addition to 1 and 0, which are binary data, has a great advantage that it may fast and efficiently perform an operation compared to a CAM that may perform a binary operation. The TCAM based on an existing complementary metal oxide semiconductor (CMOS) SRAM shows excellent durability and excellent performance, but has a disadvantage that 16 transistors per unit cell are required.

Recently, a TCAM cell structure utilizing an oxide semiconductor-based 2T0C DRAM has been disclosed. A TCAM utilizing a 2T0C DRAM that stores data in a parasitic capacitor of a cell itself includes four or six transistors (4T) or (6T) to have an advantage that an area is smaller that that of the SRAM including sixteen transistors (16T), and shows excellent durability and operation features. However, in the case of an oxide semiconductor-based 4T TCAM according to the related art, a search line SL is directly connected to source/drain electrodes of a read transistor, and thus, a voltage drop (IR drop) problem occurs, such that a signal applied to the search line is not accurately transferred to the source/drain electrodes of the read transistor. Accordingly, in order to more effectively increase a capacity of the oxide semiconductor-based TCAM, a TCAM cell structure that operates without a voltage drop problem even in a 4T TCAM rather than a 6T TCAM is required.

FIGS. 3A and 3B illustrate circuit diagrams of an oxide semiconductor 2T0C DRAM cell-based 4T TCAM cell and 6T TCAM cell according to the related art.

Referring to FIG. 3A, a TCAM cell capable of storing three states (0, 1, X) by connecting two 2T0C DRAM cells to each other and storing appropriate data in the two 2T0C DRAM cells may be configured.

However, when the TCAM cell is composed of only four transistors by simply connecting the two 2T0C DRAM cells to each other as illustrated in FIG. 3A, search lines SL are directly connected to source/drain electrodes of read transistors T₀ and T₁. Therefore, when the read transistors T₀ and T₁ are turned on, amounts of currents flowing to the search lines SL via the read transistors T₀ and T₁ are significant, and as an array size increases, a voltage drop (IR drop) significantly increases, and accordingly, signals applied to the search lines SL are not accurately transferred to the source/drain electrodes of the read transistors T₀ and T₁.

Accordingly, in order to perform large-scale parallel processing required in an artificial intelligence field, two transistors (denoted by an alternate long and short dash line circle) should be added to the existing four transistors and the search lines SL should be connected to gate electrodes of the two transistors, as illustrated in FIG. 3B. In this case, there is a disadvantage that the number of transistors included in one TCAM cell should be increased by 50% compared to the circuit illustrated in FIG. 3A, and thus, a structure capable of reducing a TCAM cell area while preventing a voltage drop is required.

As described above, the 2T0C DRAM cell does not leak the charge stored in the gate of the read transistor, which is the storage node, to the outside in a process of detecting the current flowing in the search line via the read transistor compared to a 1T1C DRAM cell, and may thus perform a non-destructive read operation to be advantageous for being applied to the TCAM.

In addition, a non-volatile memory-based TCAM such as a ferroelectric field effect transistor (FET) or a resistive random access memory (RRAM) has been proposed in order to minimize a unit cell area, but has a limitation that durability is relatively poor. Accordingly, in order to complement disadvantages of the existing proposed TCAM elements, a new TCAM technology that minimizes the unit cell area by minimizing the number of transistors per unit cell and has excellent durability and operation characteristics should be proposed.

### RELATED ART DOCUMENT

### Patent Document

(Patent Document 1) Korean Patent No. 10-1413657 (Jun. 24, 2014)

### SUMMARY

An object of the present disclosure provides a 4T ternary content addressable memory (TCAM) cell in which one unit cell is composed of four oxide semiconductor transistors by utilizing oxide semiconductor transistors having a dual-gate structure.

Another object of the present disclosure provides a 4T TCAM cell array including a plurality of 4T TCAM cells in which one unit cell is composed of four oxide semiconductor transistors including a dual-gate structure.

Still another object of the present disclosure provides a method for writing information to a 4T TCAM cell in which one unit cell is composed of four oxide semiconductor transistors by utilizing oxide semiconductor transistors having a dual-gate structure.

Objects of the present disclosure are not limited to the above-described objects, and other objects that are not mentioned may be obviously understood by those having ordinary skill in the art to which the present disclosure pertains from the following description.

According to an embodiment of the present disclosure, a 4T TCAM cell is connected to one word line, one match line, a bit line, a reverse bit line, a search line, and a reverse search line, and includes: a first write transistor that is a single-gate transistor; a second write transistor that is a single-gate transistor; a first read transistor that is a dual-gate transistor; and a second read transistor that is a dual-gate transistor, wherein the first read transistor, the second read transistor, the first write transistor and the second write transistor are implemented as oxide semiconductors.

According to another embodiment of the present disclosure, a 4T TCAM cell array includes: a plurality of 4T TCAM cells as described above, wherein each of the plurality of the 4T TCAM cells is connected to one word line, one match line, a bit line, a reverse bit line, a search line, and a reverse search line.

According to still another embodiment of the present disclosure, a method for writing information to the 4T TCAM cell as described above includes: activating the word line; selecting information to be written to the 4T TCAM cell; and writing information to the 4T TCAM cell by applying voltages determined according to the information selected in the selecting to the bit line and the reverse bit line.

Objects of the present disclosure are not limited to the above-described objects, and other objects that are not mentioned may be obviously understood by those having ordinary skill in the art to which the present disclosure pertains from the following description.

### BRIEF DESCRIPTION OF DRAWINGS

FIG. 1 illustrates an embodiment of a 2T0C dynamic random access memory (DRAM) cell according to the related art.

FIG. 2 illustrates an oxide semiconductor 2T0C DRAM cell circuit and retention characteristics of an oxide semiconductor 2T0C DRAM cell.

FIGS. 3A and 3B illustrate circuit diagrams of an oxide semiconductor 2T0C DRAM cell-based 4T ternary content addressable memory (TCAM) cell and 6T TCAM cell according to the related art.

FIG. 4 illustrates an embodiment of a 4T TCAM cell according to the present disclosure.

FIG. 5 illustrates another embodiment of a 4T TCAM cell according to the present disclosure.

FIGS. 6A to 6D illustrate cross-sectional views of circuits and structures of a 4T TCAM cell utilizing a dual-gate transistor.

FIG. 7 illustrates a TCAM cell configured by connecting two 2T0C DRAM cells to each other.

FIG. 8 illustrates signals applied to respective signal lines and data stored in D1/D2 during a write operation.

FIG. 9 illustrates changes in threshold voltages of read transistors according to stored data.

FIG. 10 illustrates a match state of search ‘1’.

FIG. 11 illustrates a match state of search ‘0’.

FIG. 12 illustrates a mismatch state of search ‘1’.

FIG. 13 illustrates a mismatch state of search ‘0’.

FIG. 14 illustrates don't care X.

FIG. 15 illustrates a method for writing information to the 4T TCAM cell.

FIGS. 16A to 16C illustrate an example of a 4T TCAM cell array.

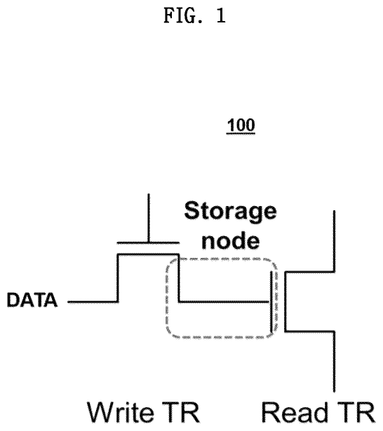

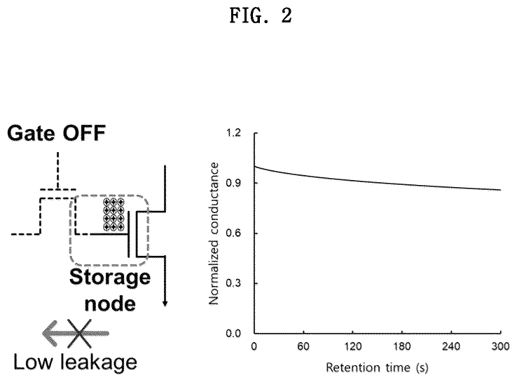

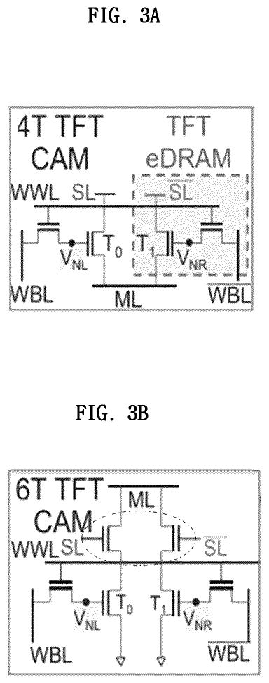

### DETAILED DESCRIPTION

In order to sufficiently understand the present disclosure, operational advantages of the present disclosure, and objects accomplished by an embodiment of the present disclosure, the accompanying drawings illustrating an embodiment of the present disclosure and contents described in the accompanying drawings should be referred.

Hereinafter, embodiments of the present disclosure will be described in detail with reference to the accompanying drawings. The same reference numerals in each drawing denote the same components.

The present disclosure proposes a 2T0C dynamic random access memory (DRAM) cell-based ternary content addressable memory (TCAM) cell utilizing an oxide semiconductor having a very low leakage current. A 4T TCAM cell according to the present disclosure e includes two dual-gate transistors serving to store data and read stored data and two single-gate transistors in charge of writing data.

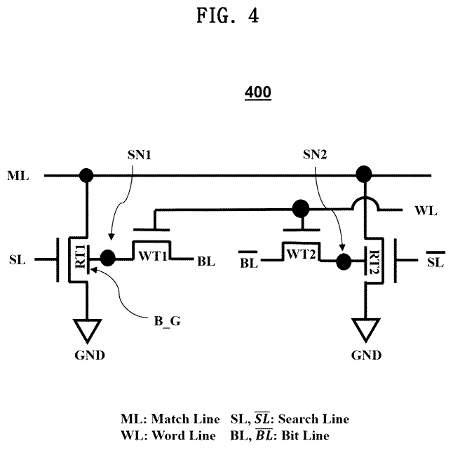

FIG. 4 illustrates an embodiment of a 4T TCAM cell according to the present disclosure. Referring to FIG. 4, a 4T TCAM cell 400 according to the present disclosure includes two read transistors RT1 and RT2 and two write transistors WT1 and WT2. Here, the two read transistors RT1 and RT2 are configured as dual-gate transistors, and the two write transistors WT1 and WT2 are configured as single-gate transistors.

Here, a dual gate refers to, for example, a top gate

and a bottom gate, and operation characteristics of the dual-gate transistor have been disclosed in the Korean Patent No. 10-1413657 (Jun. 24, 2014), and a detailed description thereof is thus omitted herein.

In FIG. 4, S̅L̅ and SL are two search lines, B̅L̅ and BL are two bit lines, the same voltage level or different voltage levels may be applied to SL and S̅L̅ depending on information to be searched, and the same voltage level or different voltage levels may also be applied to BL and B̅L̅ depending on information to be stored.

For example, when a first read transistor RT1 having a gate terminal to which SL is applied is turned on, a second read transistor RT2 having a gate terminal to which S̅L̅ is applied will be turned off. In FIG. 4, ML refers to a match line, WL refers to a word line, SN refers to a storage node, and B_G refers to a bottom gate.

Hereinafter, for convenience of explanation, assumes that SL is a search line, S̅L̅ is a reverse search line, BL is a bit line, and B̅L̅ is a reverse bit line.

Accordingly, it may be seen that in the 4T TCAM cell 400 according to the present disclosure, one word line WL, one match line ML, two search lines SL and S̅L̅, and two bit lines BL and B̅L̅ are connected, respectively.

Referring to FIG. 4, the 4T TCAM cell 400 according to the present disclosure includes a first write transistor WT1, a first read transistor RT1, a second write transistor WT2, and a second read transistor RT2.

The first write transistor WT1 has one terminal connected to the bit line BL and a gate terminal connected to the word line WL.

The first read transistor RT1 has one terminal connected to the match line ML, the other terminal connected to a ground voltage GND, a top gate terminal connected to the search line SL, and a bottom gate terminal connected to the other terminal of the first write transistor WT1. A common node between the bottom gate terminal and the other terminal of the first write transistor WT1 becomes a first storage node SN1.

The second write transistor WT2 has one terminal connected to the reverse bit line B̅L̅ and a gate terminal connected to the word line WL.

The second read transistor RT2 has one terminal connected to the match line ML, the other terminal connected to the ground voltage GND, a top gate terminal connected to the reverse search line S̅L̅, and a bottom gate terminal connected to the other terminal of the second write transistor WT2. A common node between the bottom gate terminal and the other terminal of the second write transistor WT2 becomes a second storage node SN2.

Since two search lines SL and S̅L̅ having different voltage levels are connected to the gate electrodes of the two read transistors RT1 and RT2, respectively, currents do not flow from the two search lines SL and S̅L̅ to the gate electrodes of the two read transistors RT1 and RT2, and thus, a voltage drop (IR drop) due to resistance components of the two search lines SL and S̅L̅ may be significantly reduced. The 4T TCAM cell 400 according to the present disclosure may be composed of only four oxide semiconductor transistors WT1, WT2, RT1, and RT2 and thus, the number of transistors may be reduced from 6 to 4 by 30% compared to a TCAM cell according to the related art utilizing oxide semiconductor transistors and may be reduced by 75% compared to a commercialized SRAM-based 16T TCAM including 16 transistors, such that a manufacturing cost of the TCAM cell may be minimized.

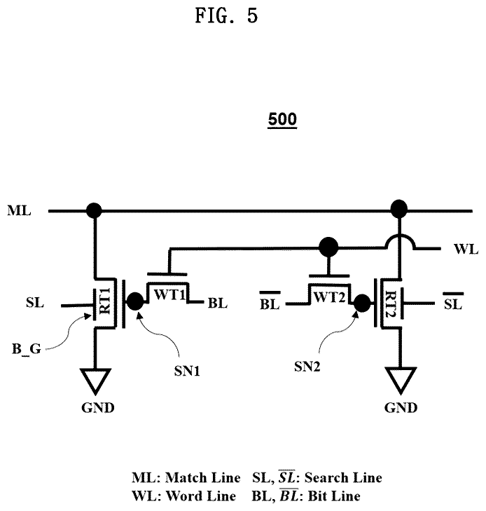

FIG. 5 illustrates another embodiment of a 4T TCAM cell according to the present disclosure.

Referring to FIG. 5, it may be seen that a 4T TCAM cell 500 according to the present disclosure is the same as that of an embodiment illustrated in FIG. 4 except that connections of the top gate terminals and the bottom gate terminals of the two read transistors WT1 and WT2 configured as dual-gate transistors are exchanged with those of an embodiment illustrated in FIG. 4.

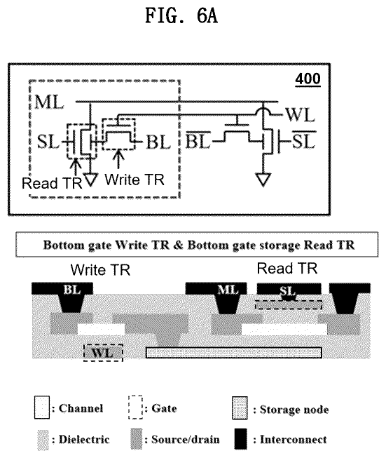

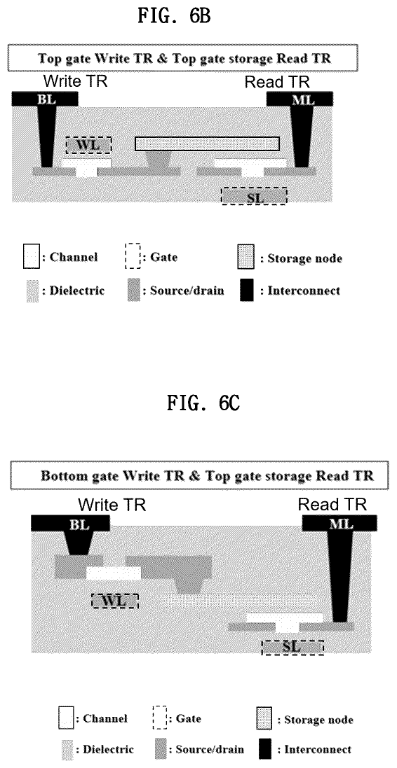

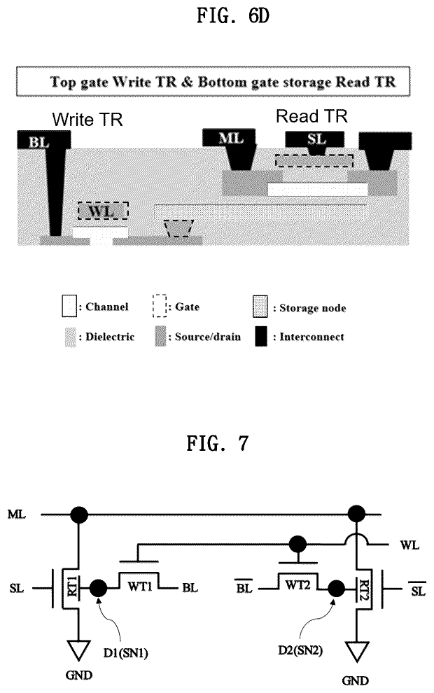

FIGS. 6A to 6D illustrate cross-sectional views of circuits and structures of 4T TCAM cells utilizing a dual-gate transistor.

Referring to FIG. 6A to 6D, it may be seen that a 4T TCAM cell 400 proposed in the present disclosure may be implemented in four embodiments depending on where a gate of a write transistor implemented with a single-gate transistor will be disposed and where data will be stored.

FIG. 6A illustrates an example of a bottom-gate structure in which gates of two transistors WT and RT are located at the bottom, FIG. 6B illustrates an example of a top-gate structure in which gates of two transistors WT and RT are located at the top, FIG. 6C illustrates an example in which a write transistor has a bottom-gate structure and a read transistor has a top-gate structure, and FIG. 6D illustrates an example in which a write transistor has a top-gate structure and a read transistor has a bottom-gate structure.

Although structures are different from each other, examples of FIGS. 6A to 6D basically have in common that a word line is connected to a gate electrode of a write transistor, a match line is connected to a drain electrode of a read transistor, and a bit line is connected to a source/drain electrode of the write transistor.

In particular, examples of FIGS. 6A to 6D have a structure in which a search line is connected to a gate electrode of the read transistor to allow a current to hardly flow, and accordingly, a voltage drop problem due to resistance is solved.

Hereinafter, an operation of the 4T TCAM cell according to the present disclosure will be described.

First, a write operation is described.

FIG. 7 illustrates a TCAM cell configured by connecting two 2T0C DRAM cells to each other.

For convenience of explanation, data stored in a first storage node SN1 of a 2T0C DRAM cell on the left side of FIG. 7 is named D1, and data stored in a second storage node SN2 of a 2T0C DRAM cell on the right side of FIG. 7 is named D2.

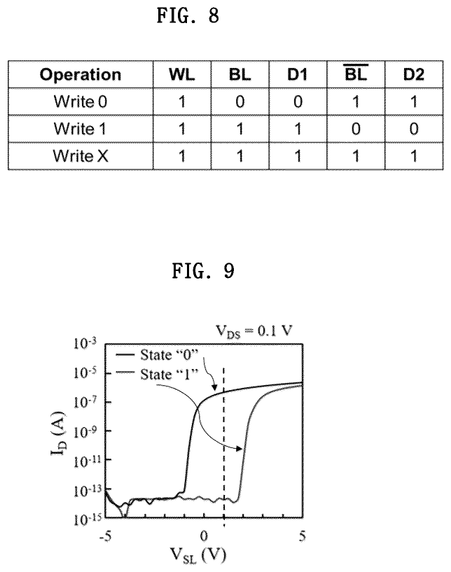

FIG. 8 illustrates signals applied to respective signal lines and data stored in D1/D2 during a write operation.

Referring to FIGS. 7 and 8, in a write operation, in order to store data D1 and D2 in two storage nodes SN1 and SN2, a positive voltage 1 is first applied to a word line WL, such that both of two write transistors WT1 and WT2 are turned on.

In a state in which both of the two write transistors WT1 and WT2 are turned on, when desired signals are applied to two bit lines BL and B̅L̅, charges are injected into the two storage nodes SN1 and SN2 through the two write transistors WT1 and WT2, such that the data D1 and D2 are stored in the two storage nodes SN1 and SN2, respectively. In this state, when the signal 1 applied to the word line WL is lowered to a low voltage level 0 so that the two write transistors WT1 and WT2 are turned off, the stored data D1 and D2 are retained as they are.

In an embodiment, threshold voltages Vₜₕ of two read transistors RT1 and RT2 are changed in a positive direction by applying 0 V as a signal marked as “0” to a bit line BL and applying −3 V as a signal marked as “1” to a reverse bit line B̅L̅.

A condition for writing specific information to the 4T TCAM cell 400 according to the present disclosure is described.

Referring to FIG. 8, it may be seen that when ‘0’ is written to the 4T TCAM cell 400, the data D1 stored in the first storage node SN1 is ‘0’ and the data D2 stored in the second storage node SN2 is ‘1’. In this case, a voltage corresponding to a value of ‘0’ is applied to the bit line BL, and a voltage corresponding to the value of ‘1’ is applied to the reverse bit line B̅L̅.

When information ‘1’ is written to the 4T TCAM cell 400, the data D1 stored in the first storage node SN1 is ‘1’, the data D2 stored in the second storage node SN2 is ‘0’, a voltage corresponding to a value of ‘1’ is applied to the bit line BL, and a voltage corresponding to the value of ‘0’ is applied to the reverse bit line B̅L̅.

When don't care information ‘X’ is written to the 4T TCAM cell 400, both of the data D1 and the data D2 respectively stored in the first storage node SN1 and the second storage node SN2 are ‘1’, and a voltage corresponding to a value of ‘1’ is applied to both of the bit line BL and the reverse bit line B̅L̅.

Referring to FIG. 8, it may be seen that when information stored in the 4T TCAM cell 400 is ‘1’ or ‘0’, the data values stored simultaneously in the two storage nodes SN1 and SN2 are different from each other, but when the stored information is don't care, the data values stored simultaneously in the two storage nodes SN1 and SN2 have the same value of ‘1’.

An embodiment in which when the information stored in the 4T TCAM cell 400 is don't care, the data values stored simultaneously in the two storage nodes SN1 and SN2 have the same value of ‘0’ is also possible.

FIG. 9 illustrates changes in threshold voltages Vₜₕ of read transistors according to stored data.

Referring to FIG. 9, it may be seen that threshold voltages of the read transistors RT1 and RT2 having the dual-gate structure change according to data State “0” and State “1” stored in the respective storage nodes SN1 and SN2 to show a large current I_{D} difference even at the same search line voltage V_{SL}. Referring to a dotted line of FIG. 9, due to a difference between the threshold voltages of the two read transistors, when the search line voltage is 1 V, currents flowing to the two read transistors RT1 and RT2 become 10⁻⁷ A (Ampere) and 10⁻¹³ A.

Next, a search operation is described.

In the following description, a match state refers to a case where signals search ‘1’ and search ‘0’ input to the two search lines SL and S̅L̅ and information State “1” and State “0” stored in the two storage nodes SN1 and SN2 match with each other, whereas a mismatch state refers to a case where signals search ‘1’ and search ‘0’ input to the two search lines SL and S̅L̅ and information State “1” and State “0” stored in the two storage nodes SN1 and SN2 do not match with each other. When a match and a mismatch are decided through a voltage level V_{ML} of the match line, voltages at which the read transistors may be turned off are applied to both of the search line and the reverse search line, and the match line is charged to a specific voltage level. When the match and the mismatch are decided from a current amount I_{ML} of the match line, a voltage source is applied to the match line and a current is measured.

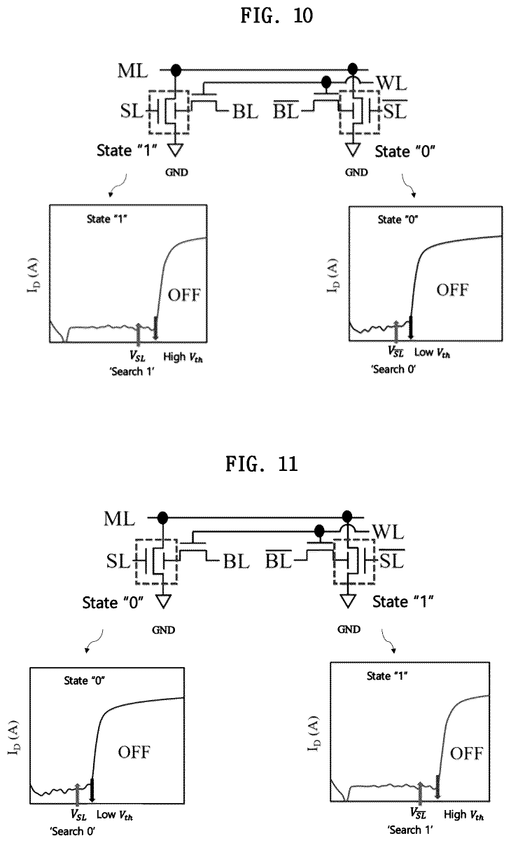

FIG. 10 illustrates a match state of search ‘1’.

FIG. 11 illustrates a match state of search ‘0’.

Referring to FIG. 10, in the match state of search ‘1’, a high voltage is applied to the search line SL and a low voltage is applied to the reverse search line S̅L̅. Referring to FIG. 11, in the match state of search ‘0’, a low voltage is applied to the search line SL and a high voltage is applied to the reverse search line S̅L̅.

When the signals search ‘1’ and search ‘0’ input to the search lines SL and S̅L̅ and the information State “1” and State “0” stored in the storage nodes SN1 and SN2 match with each other as illustrated in FIGS. 10 and 11, the threshold voltages of the read transistor RT1 and RT2 are higher than voltages corresponding to the signals search ‘1’ and search ‘0’ input to the search lines SL and S̅L̅, and thus, the match line ML is not connected to the ground voltage GND. Accordingly, the voltage level of the match line ML is retained as it is.

Next, a mismatch state is described.

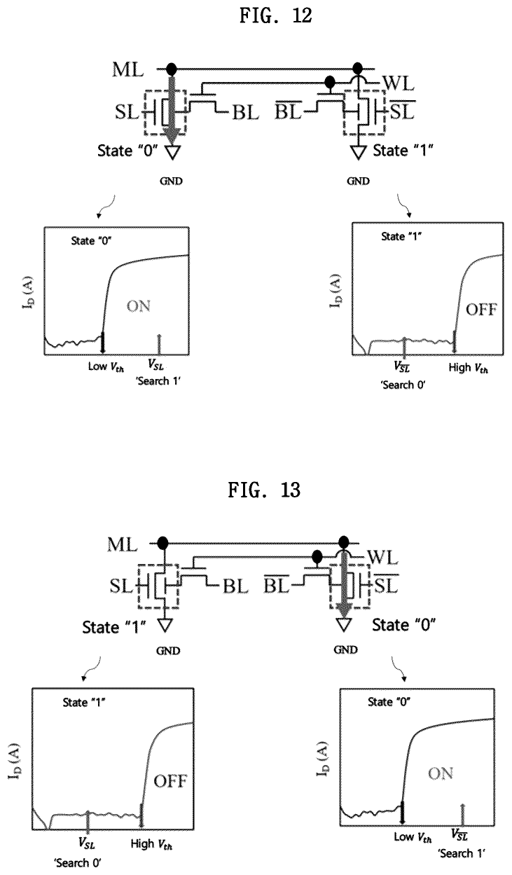

FIG. 12 illustrates a mismatch state of search ‘1’.

FIG. 13 illustrates a mismatch state of search ‘0’.

When the signals search ‘1’ and search ‘0’ input to the search lines SL and S̅L̅ and the information State “1” and State “0” stored in the storage nodes SN1 and SN2 do not match with each other as illustrated in FIGS. 12 and 13, one of the read transistors RT1 and RT2 constituting the 4T TCAM cell 400 is turned on (arrow, ON), such that the match line ML is connected to the ground voltage GND, and accordingly, a voltage drop occurs.

The match state of FIGS. 10 and 11 and the mismatch state of FIGS. 12 and 13 may be easily distinguished from each other by measuring a current flowing in the match line ML or a voltage of the match line ML. By utilizing such a feature, when information stored in the 4T TCAM cell 400 is read, different specific voltages are applied to the search line SL and the reverse search line S̅L̅ and at the same time, no voltage drop of the match line ML is measured, and when a current does not flow in the match line ML, a value corresponding to the voltage applied to the search line SL may be decided as data stored in the 4T TCAM cell 400, and conversely, a voltage drop of the match line ML is measured, and when a current flows in the match line ML, a value corresponding to a voltage opposite to the voltage applied to the search line SL may be decided as data stored in the 4T TCAM cell 400.

Next, don't care is described.

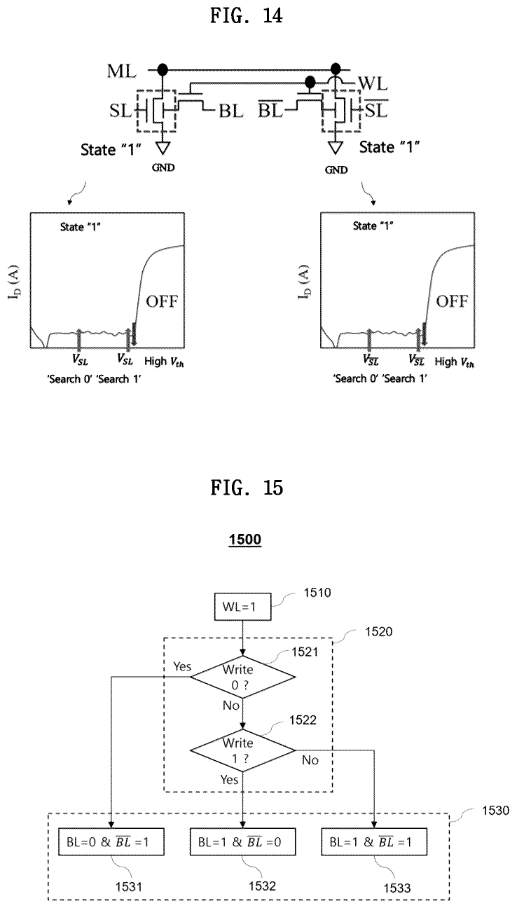

FIG. 14 illustrates don't care X.

Referring to FIG. 14, when don't care is stored in the 4T TCAM cell, two transistors WT and RT store the same state ‘1’, and both have high threshold voltages.

Since both of two data D1 and D2 have a value of ‘1’, both of the read transistors RT1 and RT2 of the 4T TCAM cell are turned off regardless of the signals input to the two search lines SL and S̅L̅, such that the match line ML and the ground voltage GND are not connected to each other, and accordingly, the same signals as those in the match state are output regardless of the signals input to the search lines SL and S̅L̅.

FIG. 15 illustrates a method for writing information to the 4T TCAM cell.

Referring to FIG. 15, a method 1500 for writing information to the 4T TCAM cell includes activating a word line WL (1510), selecting write information (1520), and writing the selected information (1530).

In the activating of the word line WL (1510), a voltage corresponding to ‘1’ is applied to the word line WL.

The selecting of the write information (1520) includes deciding whether or not information to be stored in the 4T TCAM cell is ‘0’ (1521) and deciding whether or not information to be stored in the 4T TCAM cell is ‘1’ (1522). In the selecting of the write information (1520), it is first decided whether or not the information to be stored in the 4T TCAM cell is ‘0’ (1521), and when it is decided that the information to be stored in the 4T TCAM cell is not 0 (No of 1521), it is additionally decided whether or not the information to be stored in the 4T TCAM cell is ‘1’ (1522).

In the writing of the selected information (1530), voltages corresponding to a decision result in the selecting of the write information (1520) are applied to the bit line BL and the reverse bit line B̅L̅.

When it is decided that the information to be stored in the 4T TCAM cell is ‘0’ (Yes of 1521) in the selecting of the write information (1520), a voltage corresponding to ‘0’ is applied to the bit line BL and a voltage corresponding to ‘1’ is applied to the reverse bit line B̅L̅ (1531).

When it is decided that the information to be stored in the 4T TCAM cell is ‘1’ (Yes of 1522) in the selecting of the write information (1520), a voltage corresponding to ‘1’ is applied to the bit line BL and a voltage corresponding to ‘0’ is applied to the reverse bit line B̅L̅ (1532).

When the information to be stored in the 4T TCAM cell is don't case (No of 1522) in the selecting of the write information (1520), voltages corresponding to ‘1’ are applied to the bit line BL and the reverse bit line B̅L̅ (1533).

An operation of a 4T TCAM has already been disclosed, but operation characteristics of 4T TCAM will hereinafter be briefly described in order to assist in the understanding of the present disclosure.

The 4T TCAM decides the match and the mismatch from a change in voltage level or current amount of the match line while changing the voltages applied to the search line and reverse search line after inactivating the word line.

Inactivating the word line means applying a voltage corresponding to ‘0’ to the word line so as to retain information written to the 4T TCAM cell.

When the match and the mismatch are decided through the voltage level of the match line, voltages that at which the read transistors are turned off are applied to the search line and reverse search line, the match line is pre-charged to a specific voltage level, and a change in the voltage level of the match line is then detected.

When the match and the mismatch are decided from the current amount of the match line, a current of the match line is measured while applying a voltage source to the match line.

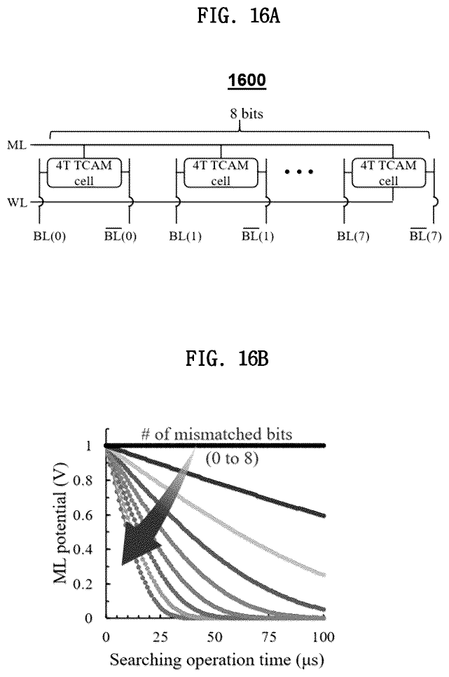

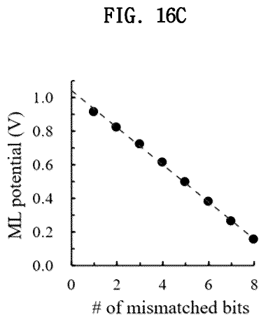

FIGS. 16A to 16C illustrate an example of a 4T TCAM cell array.

Referring to FIGS. 16A to 16C, it is assumed that information of 1011001X is stored in a 4T TCAM cell array 1600 composed of 8 bits. In this case, when information of 01110001 is searched, a total of three mismatches will occur between the information 1011001X stored in the 4T TCAM cell array 1400 and the information 01110001 to be searched, which leads to a voltage drop or a decrease in current amount depending on a method for reading information of the match line ML.

As illustrated in FIGS. 16B and 16C, the voltage drop or the decrease in current of the match line ML occurs depending on the number of mismatched states, and through this, it is possible to determine how different information to be searched and stored information are from each other.

In order to avoid complexity of the drawings, the search line SL and the reverse search line S̅L̅ have not been illustrated in FIG. 16A.

With the 4T TCAM cell utilizing dual-gate transistors, the 4T TCAM cell array, the method for writing information, and the method for reading information according to the present disclosure as described above, one cell is composed of four oxide semiconductor transistors by utilizing oxide semiconductor transistors having the dual-gate structure. Therefore, a smaller number of transistors than the number of transistors used in the related art are used, such that an area occupied in the transistors in a layout may be minimized, and accordingly, large-scale parallel processing required in an artificial intelligence field may be performed.

The effects of the present disclosure are not limited to the above-described effects, and other effects that are not mentioned will be apparently understood by those skilled in the art to which the present disclosure pertains from the following description.

The technical spirit of the present disclosure has been described hereinabove with reference to the accompanying drawings, but this is provided to describe a preferred embodiment of the present disclosure rather than restricting the present disclosure. In addition, it is obvious that various modifications and alterations may be made by those skilled in the art to which the present disclosure belongs without departing from the scope of the technical spirit of the present disclosure.

What is claimed is:

1. A 4T ternary content addressable memory (TCAM) cell connected to one word line, one match line, a bit line, a reverse bit line, a search line, and a reverse search line, comprising:
a first write transistor that is a single-gate transistor;
second write transistor that is a single-gate transistor;
a first read transistor that is a dual-gate transistor; and
a second read transistor that is a dual-gate transistor,
wherein the first read transistor, the second read transistor, the first write transistor and the second write transistor are implemented as oxide semiconductors.

2. The 4T TCAM cell of claim 1, wherein the dual-gate transistor includes a bottom gate terminal and a top gate terminal.

3. The 4T TCAM cell of claim 2, wherein the first write transistor has one terminal connected to the bit line and a gate terminal connected to the word line,
the second write transistor has one terminal connected to the reverse bit line and a gate terminal connected to the word line,
the first read transistor has one terminal connected to the match line, the other terminal connected to a ground voltage, a top gate terminal connected to the search line, and a bottom gate terminal connected to the other terminal of the first write transistor, and
the second read transistor has one terminal connected to the match line, the other terminal connected to the ground voltage, a top gate terminal connected to the reverse search line, and a bottom gate terminal connected to the other terminal of the second write transistor.

4. The 4T TCAM cell of claim 2, wherein the first write transistor has one terminal connected to the bit line and a gate terminal connected to the word line,
the second write transistor has one terminal connected to the reverse bit line and a gate terminal connected to the word line,
the first read transistor has one terminal connected to the match line, the other terminal connected to a ground voltage, a bottom gate terminal connected to the search line, and a top gate terminal connected to the other terminal of the first write transistor, and
the second read transistor has one terminal connected to the match line, the other terminal connected to the ground voltage, a bottom gate terminal connected to the reverse search line, and a top gate terminal connected to the other terminal of the second write transistor.

5. A 4T TCAM cell array comprising:
a plurality of 4T TCAM cells of claim 1,
wherein each of the plurality of the 4T TCAM cells is connected to one word line, one match line, a bit line, a reverse bit line, a search line, and a reverse search line.

6. A method for writing information to the 4T TCAM cell of claim 4, comprising:
activating the word line;
selecting information to be written to the 4T TCAM cell; and
writing information to the 4T TCAM cell by applying voltages determined according to the information selected in the selecting to the bit line and the reverse bit line.

7. The method of claim 6, wherein the information to be written to the 4T TCAM cell is ‘0’, ‘1’, and “don't care X”.

8. The method of claim 7, wherein the selecting includes:
primarily deciding whether or not information to be stored in the 4T TCAM cell is ‘0’; and
secondarily deciding whether or not the information to be stored in the 4T TCAM cell is ‘1’ when it is decided that the information to be stored in the 4T TCAM cell is not ‘0’ in the primary deciding.

9. The method of claim 8, wherein the writing of the information to the 4T TCAM cell includes:
applying a voltage corresponding to ‘0’ to the bit line and applying a voltage corresponding to ‘1’ to the reverse bit line when it is decided that the information to be stored in the 4T TCAM cell is ‘0’ in the primary deciding;
applying a voltage corresponding to ‘1’ to the bit line and applying a voltage corresponding to ‘1’ to the reverse bit line when it is decided that the information to be stored in the 4T TCAM cell is ‘1’ in the secondary deciding; and
applying voltages corresponding to ‘1’ to the bit line and the reverse bit line when it is decided that the information to be stored in the 4T TCAM cell is neither ‘0’ nor ‘1’ in the secondary deciding.
